(19) United States
(12) Patent Application Publication
(10) Pub. No.: US 2025/0268000 A1
(43) Pub. Date: Aug. 21, 2025

(54) LIGHT EMITTING ELEMENT

(71) Applicant: TOYODA GOSEI CO., LTD., Kiyosu-shi (JP)

(72) Inventors: Koichi GOSHONOO, Kiyosu-shi (JP); Koji OKUNO, Kiyosu-shi (JP)

(21) Appl. No.: 19/056,256

(22) Filed: Feb. 18, 2025

(30) Foreign Application Priority Data
Feb. 21, 2024 (JP) 2024-024848

(51) Int. Cl. H10H 29/14; H10H 29/01; H10H 29/80

(52) U.S. Cl. CPC H10H 29/14; H10H 29/011; H10H 29/8321; H10H 29/922

(57) ABSTRACT

A light emitting element containing a Group III nitride semiconductor has a first light emitting region and a second light emitting region having different emission wavelengths, the first light emitting region has a plurality of first regions, the second light emitting region has a plurality of second regions, a planar pattern of the first light emitting region and the second light emitting region is a pattern in which a plurality of units are arranged in a predetermined direction, each of the units being a pattern including one or more of the first regions and one or more of the second regions, and the plurality of first regions are electrically connected to each other in parallel, and the plurality of second regions are electrically connected to each other in parallel.

### CROSS-REFERENCE TO RELATED APPLICATION

This application is based on and claims priority under 35 USC 119 from Japanese Patent Application No. 2024-024848 filed on Feb. 21, 2024.

### TECHNICAL FIELD

The present invention relates to a light emitting element.

### BACKGROUND ART

Various light emitting elements capable of emitting full color light have been proposed. There are various full-color methods, and for example, a method in which three active layers emitting blue, green, and red light are sequentially stacked on the same substrate and an intermediate layer is inserted between the active layers is known.

A light emitting element disclosed in JP7283428B includes an n-type layer, a first active layer, a first intermediate layer, a second active layer, a second intermediate layer, a third active layer, and a cap layer sequentially stacked on a substrate from a substrate side, a first recessed portion is provided from a surface side of the cap layer to the second intermediate layer, a second recessed portion is provided from the surface side of the cap layer to the first intermediate layer, a p-type layer is provided continuously on the cap layer, on a side surface and a bottom surface of the first recessed portion, and on a side surface and a bottom surface of the second recessed portion, and a first p-side electrode to a third p-side electrode are respectively provided on the p-type layer in a region corresponding to an upper portion of the cap layer, a region corresponding to the first recessed portion, and a region corresponding to the second recessed portion. The third active layer below the first p-side electrode, the second active layer below the second p-side electrode, and the first active layer below the third p-side electrode each emit light.

### SUMMARY OF INVENTION

In the structure in JP7283428B, a light emitting region is divided into three in a plan view. In this case, the color may vary depending on a viewing angle.

The present invention has been made in view of such a background, and an object thereof is to provide a light emitting element having a reduced color variation.

A light emitting element according to an aspect of the present invention is a light emitting element containing a Group III nitride semiconductor, and has:

a first light emitting region and a second light emitting region having different emission wavelengths, in which

the first light emitting region has a plurality of first regions,

the second light emitting region has a plurality of second regions,

a planar pattern of the first light emitting region and the second light emitting region is a pattern in which a plurality of units are arranged in a predetermined direction, each of the units being a pattern including respective one or more of the first regions and the second regions, and

the plurality of first regions are electrically connected to each other in parallel, and

the plurality of second regions are electrically connected to each other in parallel.

In the above aspect, the planar pattern of the first light emitting region and the second light emitting region other than element end portions is a pattern in which units are periodically arranged in a direction parallel to a certain side of an element having a rectangular shape, each of the units being a pattern including respective two or more of the first regions and the second regions (respective one or more of the first regions and the second regions) sequentially arranged in the direction parallel to the certain side of the element having a rectangular shape, the plurality of first regions are electrically connected to each other in parallel, and the plurality of second regions are electrically connected to each other in parallel. When the planar pattern of the first light emitting region and the second light emitting region has such a configuration, a variation in light intensity of the first light emitting region and the second light emitting region due to angles is reduced.

As a result, a color variation due to a viewing angle of the light emitting element can be reduced.

As described above, according to the above aspect, it is possible to provide a light emitting element having a reduced color variation.

### BRIEF DESCRIPTION OF DRAWINGS

FIG. 1 is a cross-sectional view showing a configuration of a light emitting element according to a first embodiment, which is a cross-sectional view along a line I-I in FIG. 2A.

FIGS. 2A and 2B are each a plan view showing an electrode pattern of the light emitting element according to the first embodiment.

FIG. 3 is a diagram showing a step of producing the light emitting element according to the first embodiment.

FIG. 4 is a diagram showing a step of producing the light emitting element according to the first embodiment.

FIG. 5 is a diagram showing a step of producing the light emitting element according to the first embodiment.

FIG. 6 is a diagram showing a step of producing the light emitting element according to the first embodiment.

FIG. 7 is a diagram showing a step of producing the light emitting element according to the first embodiment.

FIG. 8 is a diagram showing a step of producing the light emitting element according to the first embodiment.

FIGS. 9A and 9B are each a plan view showing a configuration of a light emitting element according to a first modification of the first embodiment.

FIGS. 10A and 10B are each a plan view showing a configuration of a light emitting element according to a second modification of the first embodiment.

### DETAILED DESCRIPTION OF THE INVENTINO

A light emitting element containing a Group III nitride semiconductor includes: a first light emitting region and a second light emitting region having different emission wavelengths, in which the first light emitting region has a plurality of first regions, the second light emitting region has a plurality of second regions, a planar pattern of the first light emitting region and the second light emitting region is a pattern in which a plurality of units are arranged in a predetermined direction, each of the units being a pattern including respective one or more of the first regions and the second regions, and the plurality of first regions are electrically connected to each other in parallel, and the plurality of second regions are electrically connected to each other in parallel.

In the light emitting element, a planar pattern of the first regions and the second regions may be a stripe extending in a direction perpendicular to the predetermined direction, and the units may be periodically arranged in the predetermined direction. One unit may include one first region and one second region.

The light emitting element may have a rectangular shape in a plan view, and the predetermined direction may be a direction parallel to a certain side of the light emitting element having a rectangular shape.

The light emitting element may further include: a third light emitting region having an emission wavelength different from the emission wavelengths of the first light emitting region and the second light emitting region, in which the third light emitting region may have a plurality of third regions, a planar pattern of the first light emitting region, the second light emitting region, and the third light emitting region may be a pattern in which a plurality of units are arranged in the predetermined direction, each of the units being a pattern including respective one or more of the first regions, the second regions, and the third regions, and the plurality of third regions may be electrically connected to each other in parallel.

In the light emitting element, a planar pattern of the first regions, the second regions, and the third regions may be a stripe extending in a direction perpendicular to the predetermined direction, and the units may be periodically arranged in the predetermined direction. One unit may include one first region, one second region, and one third region. The light emitting element may have a rectangular shape in a plan view, and the predetermined direction may be a direction parallel to a certain side of the light emitting element having a rectangular shape.

In the light emitting element, the first light emitting region may emit red light, the second light emitting region may emit green light, and the third light emitting region may emit blue light, and an area of the first light emitting region may be larger than an area of the second light emitting region and an area of the third light emitting region. A color balance is easily adjusted.

In the light emitting element, the first light emitting region may emitting red light, the second light emitting region may emit green light, and the third light emitting region may emit blue light, and a stripe width of the first regions may be 2 to 10 times a stripe width of the second regions.

The light emitting element may include: a substrate; an n-type layer provided on the substrate and containing an n-type Group III nitride semiconductor; a first active layer provided on the n-type layer and having a predetermined band gap energy; a first intermediate layer provided on the first active layer and containing a Group III nitride semiconductor; a second active layer provided on the first intermediate layer and having a band gap energy different from the band gap energy of the first active layer; a first groove having a depth reaching the first intermediate layer from a second active layer side; a p-type layer provided on the second active layer and on a bottom surface of the first groove, and containing a p-type Group III nitride semiconductor; a first p-side contact electrode provided on the p-type layer; and a second p-side contact electrode provided on the bottom surface of the first groove, in which a region in the second active layer under the first p-side contact electrode may be the first light emitting region, and a region in the first active layer under the second p-side contact electrode may be the second light emitting region.

The light emitting element may include: a substrate; an n-type layer provided on the substrate and containing an n-type Group III nitride semiconductor; a first active layer provided on the n-type layer and having a predetermined band gap energy; a first intermediate layer provided on the first active layer and containing a Group III nitride semiconductor; a second active layer provided on the first intermediate layer and having a band gap energy different from the band gap energy of the first active layer; a second intermediate layer provided on the second active layer and containing a Group III nitride semiconductor; a third active layer provided on the second intermediate layer and having a band gap energy different from the band gap energies of the first active layer and the second active layer; a first groove having a depth reaching the second intermediate layer from a third active layer side; a second groove having a depth reaching the first intermediate layer from the third active layer side; a p-type layer provided on the third active layer, on a bottom surface of the first groove, and on a bottom surface of the second groove, and containing a p-type Group III nitride semiconductor; a first p-side contact electrode provided on the p-type layer; a second p-side contact electrode provided on the bottom surface of the first groove; and a third p-side contact electrode provided on the bottom surface of the second groove, in which a region in the third active layer under the first p-side contact electrode may be the first light emitting region, a region in the second active layer under the second p-side contact electrode may be the second light emitting region, and a region in the first active layer under the third p-side contact electrode may be the third light emitting region.

The light emitting element may further includes: a third groove having a depth reaching the n-type layer from the third active layer side; and an n-side contact electrode provided on a bottom surface of the third groove, in which the third groove and the n-side contact electrode may have a planar pattern that is a rectangular annular pattern along an outer periphery of the element.

### First Embodiment

### 1. Overview of Light Emitting Element According to First Embodiment

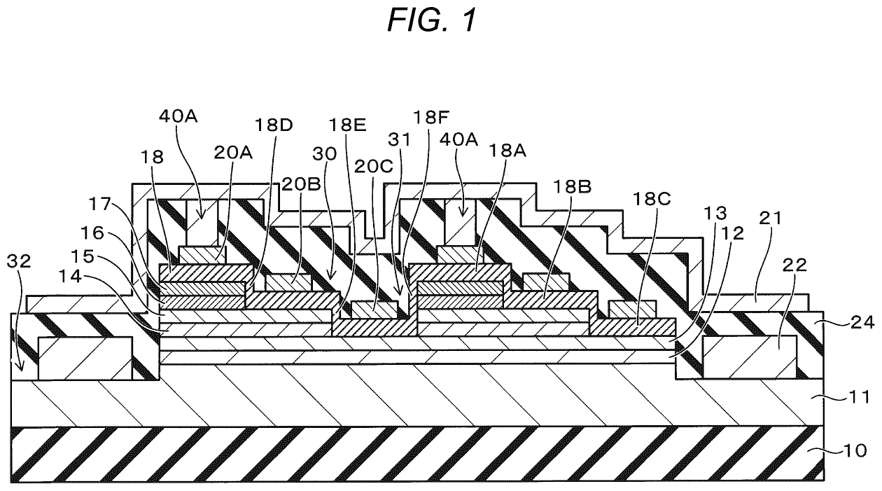

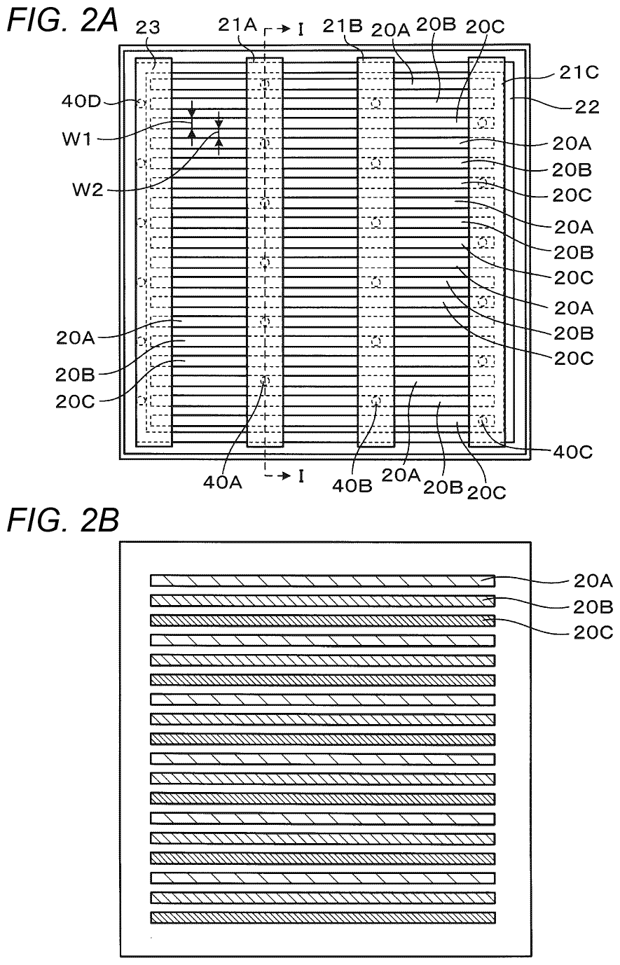

FIG. 1 is a cross-sectional view showing a configuration of a light emitting element according to a first embodiment, and is a cross-sectional view perpendicular to a main surface of a substrate. FIGS. 2A and 2B are each a plan view showing an electrode pattern of the light emitting element according to the first embodiment. FIG. 1 is a cross-sectional view taken along a line I-I in FIG. 2A. The light emitting element according to the first embodiment is of a flip chip type, and has red, green and blue light emitting regions in a plan view. The light emission of these light emitting regions can be controlled independently. Therefore, full color can be realized with one chip. In addition, the red, green and blue light emitting regions are arranged periodically, and FIG. 1 shows a structure for two periods.

### 2. Configuration of Light Emitting Element

As shown in FIG. 1, the light emitting element according to the first embodiment includes a substrate 10, an n-type layer 11, a first active layer 12, a first intermediate layer 13, a second active layer 14, a second intermediate layer 15, a third active layer 16, an electron blocking layer 17, a p-type layer 18, p-side contact electrodes 20A to 20C, p-side electrodes 21A to 21C, an n-side contact electrode 22, an n-side electrode 23, and an insulating film 24.

The substrate 10 is a growth substrate on which a Group III nitride semiconductor is grown. For example, sapphire, Si, GaN, or ScAlMgO₄(SAM).

The n-type layer 11 is an n-type semiconductor layer provided on the substrate 10 via a low-temperature buffer layer or a high-temperature buffer layer (not shown). However, the buffer layer may be provided as necessary, and may not be provided when the substrate is GaN. The n-type layer 11 is, for example, n-GaN, n-AlGaN, or n-InGaN. A Si concentration is, for example, 1×10¹⁸ cm⁻³ to 100×10¹⁸ cm⁻³.

The first active layer 12 is a light emitting layer having an SQW or MQW structure provided on the n-type layer 11. An emission wavelength is blue and is 430 nm to 480 nm. The first active layer 12 has a structure in which a barrier layer made of AlGaN and a well layer made of InGaN are alternately stacked for 1 to 9 pairs. The number of pairs is more preferably 1 to 7, and still more preferably 1 to 5.

A base layer may be provided between the n-type layer 11 and the first active layer 12 as necessary. The base layer is a semiconductor layer having a superlattice structure provided on the n-type layer 11, and is a layer for relaxing a lattice strain in a semiconductor layer formed on the base layer. The base layer is formed by alternately stacking Group III nitride semiconductor thin films having different compositions (for example, two of GaN, InGaN, and AlGaN), and the number of pairs is, for example, 3 to 30. The base layer may be non-doped or doped with Si by about 1×10¹⁷ cm⁻³ to 100×10¹⁷ cm⁻³. It is not necessary to have a superlattice structure as long as the strain can be relaxed.

In addition, an ESD layer may be provided between the n-type layer 11 and the base layer. The ESD layer is a layer provided to increase an electrostatic breakdown voltage. The ESD layer is, for example, non-doped or lightly Si-doped GaN, InGaN, or AlGaN.

The first intermediate layer 13 is a semiconductor layer provided on the first active layer 12. The first intermediate layer 13 is a layer provided to enable light emission from the first active layer 12 and light emission from the second active layer 14 to be separately controlled. The first intermediate layer 13 also serves to protect the first active layer 12 from etching damage when forming a second groove 31 to be described later.

The first intermediate layer 13 has a structure in which a non-doped intermediate layer and an n-type intermediate layer are sequentially stacked from a first active layer 12 side. The non-doped intermediate layer and the n-type intermediate layer may be made of the same material except for impurities. A reason why the first intermediate layer 13 has such a two-layer structure will be described later.

A material of the first intermediate layer 13 is an In-containing Group III nitride semiconductor, and is preferably InGaN, for example. With a surfactant effect of In, roughness on a surface of the first intermediate layer 13 can be prevented and surface flatness can be improved. In addition, the lattice strain can be relaxed.

It is sufficient that an In composition (a molar ratio of In to all Group III metals in the Group III nitride semiconductor) of the first intermediate layer 13 is set to have a band gap in which light emitted from the first active layer 12 and light emitted from the second active layer 14 are not absorbed. A preferred In composition is 10% or less, more preferably 5% or less, and still more preferably 2% or less. When the In composition is greater than 10%, the surface of the first intermediate layer 13 is rough. The In composition is any as long as it is greater than 0%, and may be at a doping level (a level that does not form a mixed crystal). For example, GaN having an In concentration of 1×10¹⁴ cm⁻³ or more and 1×10²² cm⁻³ or less.

In the first intermediate layer 13, the non-doped intermediate layer is non-doped, and the n-type intermediate layer is Si-doped. The n-type intermediate layer preferably has a Si concentration of 1×10¹⁷ cm⁻³ to 1000×10¹⁷ cm⁻³. It is preferably 10×10¹⁷ cm⁻³ to 100×10¹⁷ cm⁻³, and more preferably 20×10¹⁷ cm⁻³ to 80×10¹⁷ cm⁻³. The n-type intermediate layer may be modulated and doped with Si, or there may be a non-doped region in a partial region of the n-type intermediate layer.

A thickness of the first intermediate layer 13 is preferably 20 nm to 150 nm. When the thickness is more than 150 nm, the surface of the first intermediate layer 13 may be rough.

When the thickness is less than 20 nm, there is a possibility that it is difficult to control a depth of the second groove 31 to be within the non-doped intermediate layer when forming the second groove 31 to be described later. The thickness is more preferably 30 nm to 100 nm, and still more preferably 50 nm to 80 nm.

In addition, a thickness of the non-doped intermediate layer of the first intermediate layer 13 is preferably 10 nm or more. This is for controlling an etching depth and avoiding etching damage to the first active layer 12. In addition, a thickness of the n-type intermediate layer of the first intermediate layer 13 is preferably 10 nm or more. This is for independently controlling light emitting characteristics of each active layer.

The second active layer 14 is a layer provided on the first intermediate layer 13, and has a quantum well structure of SQW or MQW. An emission wavelength is green and is 510 nm to 570 nm. The quantum well structure has a structure in which a barrier layer made of GaN or AlGaN and a well layer made of InGaN are alternately stacked for 1 to 7 pairs.

A strain relaxation layer may be provided between the first intermediate layer 13 and the second active layer 14. When the strain relaxation layer is provided, a strain in the second active layer 14 stacked thereon can be relaxed, and a crystal quality can be improved. The strain relaxation layer has an SQW structure or an MQW structure in which a barrier layer and a well layer are sequentially stacked, and has a quantum well structure in which a thickness of the well layer is adjusted to be small so as not to emit light. For example, when a thickness of the well layer is set to 1 nm or less, it is possible to prevent the well layer from emitting light. The barrier layer is AlGaN, and the well layer is InGaN. It is sufficient that a wavelength corresponding to a band edge energy in the well layer of the strain relaxation layer is shorter than the emission wavelength of the second active layer 14, and is, for example, 400 nm to 460 nm when the emission wavelength is 500 nm to 560 nm.

The second intermediate layer 15 is a semiconductor layer provided on the second active layer 14. The second intermediate layer 15 is provided for a reason same as that of the first intermediate layer 13, and is a layer provided to enable light emission from the second active layer 14 and light emission from the third active layer 16 to be separately controlled. In addition, it also has a role of protecting the second active layer 14 from etching damage when forming a first groove 30 to be described later.

The second intermediate layer 15 has a structure in which a non-doped intermediate layer and an n-type intermediate layer are sequentially stacked from a second active layer 14 side. The non-doped intermediate layer and the n-type intermediate layer have a structure same as that of the non-doped intermediate layer and the n-type intermediate layer of the first intermediate layer 13. That is, the non-doped intermediate layer and the n-type intermediate layer of the second intermediate layer 15 are made of a material same as that of the non-doped intermediate layer and the n-type intermediate layer of the first intermediate layer 13 except for impurities, and a thickness range is also the same. In the second intermediate layer 15, the non-doped intermediate layer is non-doped, and the n-type intermediate layer is Si-doped. A Si concentration in the n-type intermediate layer of the second intermediate layer 15 is in a range same as the Si concentration in the n-type intermediate layer of the first intermediate layer 13, and may be the same concentration.

The third active layer 16 is a layer provided on the second intermediate layer 15, and has a quantum well structure of SQW or MQW. An emission wavelength is red and is 590 nm to 700 nm. The quantum well structure has a structure in which a barrier layer made of InGaN and a well layer made of InGaN are alternately stacked for 1 to 7 pairs. The number of pairs is more preferably 1 to 5, and still more preferably 1 to 3.

A strain relaxation layer may be provided between the second intermediate layer 15 and the third active layer 16. When the strain relaxation layer is provided, a strain in the third active layer 16 stacked thereon can be relaxed, and the crystal quality can be improved. The strain relaxation layer has, for example, a structure in which a first strain relaxation layer and a second strain relaxation layer are sequentially stacked from a second intermediate layer 15 side.

The first strain relaxation layer and the second strain relaxation layer have a structure same as the strain relaxation layer between the first intermediate layer 13 and the second active layer 14 described above. A wavelength corresponding to a band edge energy in a well layer of the first strain relaxation layer is, for example, 400 nm to 460 nm. In the second strain relaxation layer, a wavelength corresponding to a band edge energy in a well layer of the second strain relaxation layer is, for example, 510 nm to 570 nm.

The electron blocking layer 17 is a semiconductor layer provided on the third active layer 16. The electron blocking layer 17 is a layer for blocking electrons implanted from the n-type layer 11 in order to efficiently confine the electrons in the third active layer 16. In addition, the electron blocking layer 17 is layer not only having an electron blocking function but also functioning as a protective layer for protecting the third active layer 16. The electron blocking layer 17 may be made of a material having a band gap wider than that of the well layer of the third active layer 16, such as AlGaN, GaN, or InGaN. A thickness of the electron blocking layer 17 is preferably 2.5 nm to 50 nm, and more preferably 5 nm to 25 nm. The electron blocking layer 17 may be doped with impurities or Mg. In this case, a Mg concentration is preferably 1×10¹⁸ cm⁻³ to 1000×10¹⁸ cm⁻³.

A partial region on a surface of the electron blocking layer 17 is etched to provide grooves, and from the electron blocking layer 17, the first groove 30 reaching the second intermediate layer 15, the second groove 31 reaching the first intermediate layer 13, and a third groove 32 reaching the n-type layer 11 are provided. A planar pattern of the first groove 30 and the second groove 31 is a stripe, which is a pattern aligned with the p-side contact electrodes 20A to 20C to be described later. In addition, a planar pattern of the third groove 32 is a square annular pattern along an outer periphery of the element.

The first groove 30 has a depth reaching the non-doped intermediate layer of the second intermediate layer 15. In this way, by removing the n-type intermediate layer of the second intermediate layer 15 below the p-side electrode 21B, the n-type intermediate layer is not positioned on the second active layer 14, and the second active layer 14 emits light. The second groove 31 has a depth reaching the non-doped intermediate layer of the first intermediate layer 13. For the same reason, by removing the n-type intermediate layer of the first intermediate layer 13 below the p-side electrode 21C, the n-type intermediate layer is not positioned on the first active layer 12, and the first active layer 12 emits light.

The p-type layer 18 is a semiconductor layer provided continuously in the form of a film on the electron blocking layer 17, on a side surface and a bottom surface of the first groove 30, and on a side surface and a bottom surface of the second groove 31. In the p-type layer 18, a region on the electron blocking layer 17 is defined as a region 18A, a region on the bottom surface of the first groove 30 (on the second intermediate layer 15) is defined as a region 18B, and a region on the bottom surface of the second groove 31 (on the first intermediate layer 13) is defined as a region 18C. In addition, in the p-type layer 18, a region that connects the region 18A and the region 18B is defined as a region 18D, a region that connects the region 18B and the region 18C is defined as a region 18E, and a region that connects the region 18C and the region 18A is defined as a region 18F. The p-type layer 18 is composed of a second electron blocking layer, a first layer, and a second layer sequentially from an electron blocking layer 17 side. Note that, the regions 18D to 18F may not be formed or may be removed by etching to physically separate the regions 18A to 18C.

The second electron blocking layer is provided on the electron blocking layer 17, on the non-doped intermediate layer exposed on the bottom surface of the first groove 30, and on the non-doped intermediate layer exposed on the bottom surface of the second groove 31, and is a layer for blocking electrons implanted from the n-type layer 11 in order to efficiently confine the electrons in the first active layer 12, the second active layer 14, and the third active layer 16.

The second electron blocking layer may be a single layer of GaN or AlGaN, a structure in which two or more of AlGaN, GaN, and InGaN are stacked, or a structure in which they are stacked with only a composition ratio changed. Alternatively, the second electron blocking layer may have a superlattice structure. Having a superlattice structure, the electrons can be more efficiently blocked. The superlattice structure is, for example, a structure in which p-AlGaN and p-InGaN are alternately stacked, or a structure in which p-AlGaN and p-GaN are alternately stacked.

A thickness of the second electron blocking layer is preferably 5 nm to 50 nm, and more preferably 5 nm to 25 nm. In addition, the second electron blocking layer is of a Mg-doped p-type. When the second electron blocking layer is of a p-type, holes can be efficiently implanted into the active layer. In addition, a larger barrier can be provided to electrons, and an electron blocking function can be improved. The second electron blocking layer may be non-doped for the reasons described above, and is preferably doped with Mg to be of a p-type. A Mg concentration in the second electron blocking layer is preferably 1×10¹⁹ cm⁻³ to 100×10¹⁹ cm⁻³.

The first layer is preferably p-GaN or p-InGaN. A thickness of the first layer is preferably 10 nm to 500 nm, more preferably 10 nm to 200 nm, and still more preferably 10nm to 100 nm. A Mg concentration in the first layer is preferably 1×10¹⁹ cm⁻³ to 100×10¹⁹ cm⁻³. The second layer is preferably p-GaN or p-InGaN. A thickness of the second layer is preferably 2 nm to 50 nm, more preferably 4 nm to 20 nm, and still more preferably 6 nm to 10 nm. A Mg concentration in the second layer is preferably 1×10²⁰ cm⁻³ to 100×10²⁰ cm⁻³.

The p-side contact electrodes 20A to 20C are electrodes provided on the region 18A, the region 18B, and the region 18C, respectively. A material of the p-side contact electrodes 20A to 20C is a transparent electrode such as ITO or IZO. A transparent electrode and a reflective electrode may be sequentially stacked or a transparent electrode and a DBR may be stacked from a p-type layer 18 side.

The n-side contact electrode 22 is an electrode provided on the n-type layer 11 exposed on a bottom surface of the third groove 32. When the substrate 10 is made of a conductive material, the n-side contact electrode 22 may be provided on a back surface of the substrate 10 without providing the third groove 32. A material of the n-side contact electrode 22 is, for example, Ti/Al or V/Al.

The insulating film 24 is provided to cover the p-side contact electrodes 20A to 20C, the p-type layer 18, the n-side contact electrode 22, and a side surface and the bottom surface of the third groove 32. The insulating film 24 is made of SiO₂, for example. Holes 40A to 40D penetrating the insulating film 24 are provided at predetermined positions of the insulating film 24. The holes 40A to 40D have a circular shape. The holes 40A to 40D may also have a polygonal shape such as a square shape or a rectangle shape. The number of each of the holes 40A to 40C is the same as the number of each of the p-side contact electrodes 20A to 20C, and the holes 40A to 40C are arranged in a direction perpendicular to a strip direction.

The p-side electrodes 21A to 21C are electrodes provided on the insulating film 24. The p-side electrodes 21A to 21C are connected to the p-side contact electrodes 20A to 20C via the holes 40A to 40C formed in the insulating film 24, respectively. A material of the p-side electrodes 21A to 21C is, for example, Ti/Au. In addition, a metal having a high reflectance may be provided at an interfaces between the p-side electrodes 21A to 21C and the p-side contact electrodes 20A to 20C. For example, Ag, Al, Rh, or Ru.

The n-side electrode 23 is an electrode provided on the insulating film 24. The n-side electrode 23 is connected to the n-side contact electrode 22 via the hole 40D formed in the insulating film 24. A material of the n-side electrode 23 is, for example, Ti/Au. In the first embodiment, a plurality of holes 40D are provided and the holes 40D are arranged in the stripe direction, but the number of holes 40D may be one.

In the light emitting element according to the first embodiment, when a forward voltage is applied between the p-side electrode 21A and the n-side electrode 23, the third active layer 16 under the p-side contact electrode 20A emits light; when a forward voltage is applied between the p-side electrode 21B and the n-side electrode 23, the second active layer 14 under the p-side contact electrode 20B emits light; and when a forward voltage is applied between the p-side electrode 21C and the n-side electrode 23, the first active layer 12 below the p-side contact electrode 20C emits light. A planar pattern of light emission from the first active layer 12, the second active layer 14, and the third active layer 16 is substantially the same as a planar pattern of the p-side contact electrodes 20A to 20C. These light emitting regions correspond to a first light emitting region to a third light emitting region according to the present invention.

### 3. Planar Pattern of Light Emitting Element

A planar pattern of the light emitting element according to the first embodiment will be described with reference to FIGS. 2A and 2B. Note that, in FIG. 2A, the first groove 30, the second groove 31, and the third groove 32 are omitted. FIG. 2B shows only the planar pattern of the p-side contact electrodes 20A to 20C, in which the planar pattern of the p-side contact electrode 20A substantially coincides with a planar pattern of a red light emitting region, the planar pattern of the p-side contact electrode 20B substantially coincides with a planar pattern of a green light emitting region, and the planar pattern of the p-side contact electrode 20C substantially coincides with a planar pattern of a blue light emitting region.

As shown in FIGS. 2A and 2B, the light emitting element according to the first embodiment has a square shape. A length of one side of the square is, for example, 50 μm to 1 mm. The third groove 32 is provided in a square annular shape along the outer periphery of the element, and the n-side contact electrode 22 is also in a square annular shape.

Note that, the pattern of the third groove 32 and the n-side contact electrode 22 is not limited to being annular, but may be linear, L-shaped, or the like. When the element has a large area, it is preferable to use a annular pattern as in the first embodiment. The current can be sufficiently diffused within the plane to achieve uniform light emission. For example, when a long side of the light emitting element having a rectangular shape is 200 μm or more, the annular pattern as in the first embodiment is preferred.

The p-side contact electrodes 20A to 20C each have a long rectangular shape (stripe) as the planar pattern. The stripe direction is arranged to be parallel to one side of the element having a square shape. In addition, units are periodically arranged in a direction perpendicular to the stripe direction, each of the units being a pattern including the p-side contact electrode 20A, the p-side contact electrode 20B, and the p-side contact electrode 20C sequentially arranged in the direction perpendicular to the stripe direction.

Since the planar pattern of the p-side contact electrodes 20A to 20C is the pattern described above, it is possible to reduce a color variation due to an angle when the light emitted from the light emitting element is viewed. That is, since the light emitting regions of respective colors are continuous in the stripe direction, the light emission of respective colors is uniform, and since the colors are alternately and periodically arranged in the direction perpendicular to the stripe direction, the light emission of respective colors is nearly uniform. As a result, the color variation is reduced regardless of the viewing angle.

The p-side contact electrodes 20A to 20C have an equal stripe width W1, for example, 5 μm to 50 μm. Within this range, the color variation due to the viewing angle can be further reduced. The width W1 is more preferably 5 μm to 30 μm, and still more preferably 5 μm to 10 μm. For the same reason, W1 is preferably 0.01 to 0.2 times, more preferably 0.01 to 0.1 times, and still more preferably 0.01 to 0.05 times a length of a short side of the light emitting element.

The p-side contact electrodes 20A to 20C have an equal stripe interval W2, and W2 is, for example, 1 μm to 10 μm. Within this range, the color variation due to the viewing angle can be further reduced.

When an arrangement of three stripes in the order of the p-side contact electrode 20A, the p-side contact electrode 20B, and the p-side contact electrode 20C is defined as one unit, the number of units is preferably 2 to 20. FIGS. 2A and 2B show a case where the number of units is six. However, in FIG. 1, it is simplified to two units. When the number of units is within this range, the color variation due to the viewing angle can be further reduced. The number of units is more preferably 5 to 20, and still more preferably 10 to 20.

The p-side contact electrodes 20A to 20C preferably have a stripe length of 0.5 to 0.95 times a length of one side of the element having a square shape. When a sufficient stripe length is ensured, it is possible to improve uniformity of light emission in the stripe direction, and to further reduce the color variation due to the viewing angle. The length is more preferably 0.8 to 0.95 times, and is still more preferably 0.9 to 0.95 times.

Planar patterns of the p-side electrodes 21A to 21C and the n-side electrode 23 are rectangular as shown in FIG. 2A, and an arrangement is made such that the direction perpendicular to the stripe direction of the p-side contact electrodes 20A to 20C is the long side. The n-side electrode 23, the p-side electrode 21A, the p-side electrode 21B, and the p-side electrode 21C are sequentially arranged at an equal interval. Since the p-side contact electrodes 20A to 20C are each in a stripe pattern, the p-side contact electrodes 20A can be connected to each other, the p-side contact electrodes 20B can be connected to each other, and the p-side contact electrodes 20C can be connected to each other by a simple rectangular pattern perpendicular thereto.

As described above, in the light emitting element according to the first embodiment, the planar pattern of the p-side contact electrodes 20A to 20C is a stripe, the p-side contact electrode 20A, the p-side contact electrode 20B, and the p-side contact electrode 20C are sequentially arranged as one unit, and the units are arranged periodically. In addition, the p-side contact electrodes 20A are electrically connected to each other in parallel, the p-side contact electrodes 20B are electrically connected to each other in parallel, and the p-side contact electrodes 20C are electrically connected to each other in parallel through the p-side electrodes 21A to 21C. Therefore, the color variation due to the viewing angle of the light emitting element can be reduced.

### 4. Steps of Producing Light Emitting Element

Next, steps of producing the light emitting element according to the first embodiment will be described with reference to the drawings.

First, the substrate 10 is prepared, and the substrate is subjected to a heat treatment by adding hydrogen, nitrogen, and, if necessary, ammonia.

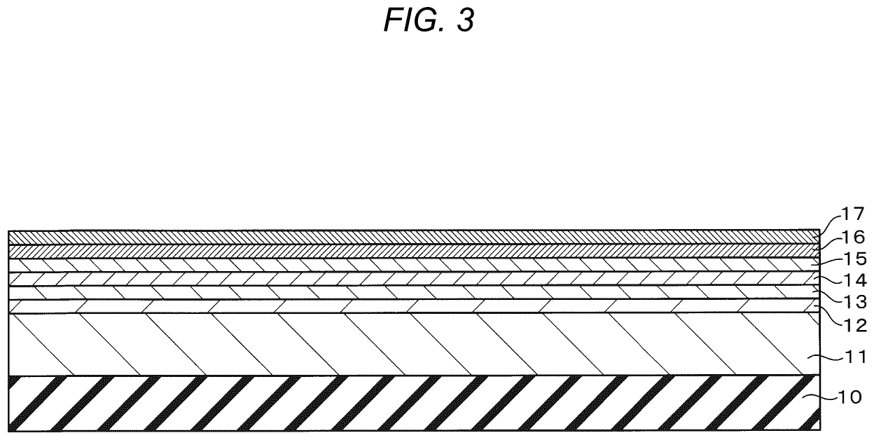

Next, a buffer layer is formed on the substrate 10, and the n-type layer 11, the first active layer 12, the first intermediate layer 13, the second active layer 14, the second intermediate layer 15, the third active layer 16, the electron blocking layer 17, and the p-type layer 18 are sequentially formed on the buffer layer (see FIG. 3). Each layer is formed by using a MOCVD method.

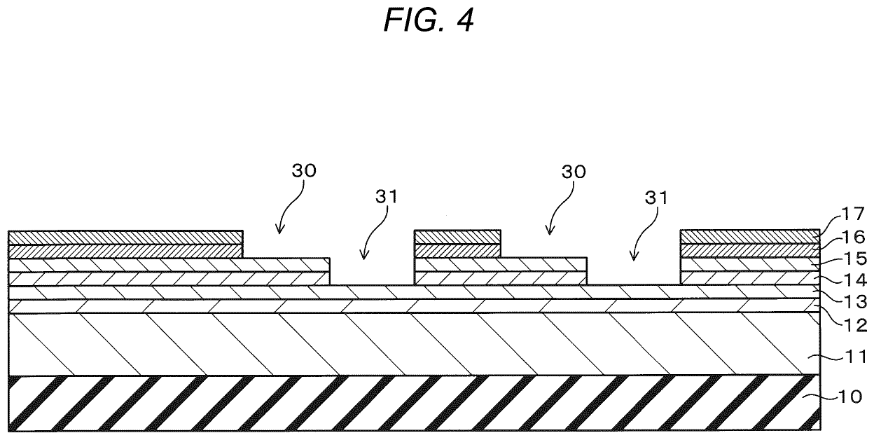

Next, a partial region on a surface of the p-type layer 18 is dry-etched until it reaches the non-doped intermediate layer of the second intermediate layer 15 to form the first groove 30, and is dry-etched until it reaches the non-doped intermediate layer of the first intermediate layer 13 to form the second groove 31 (see FIG. 4). The planar pattern of the first groove 30 and the second groove 31 is a stripe.

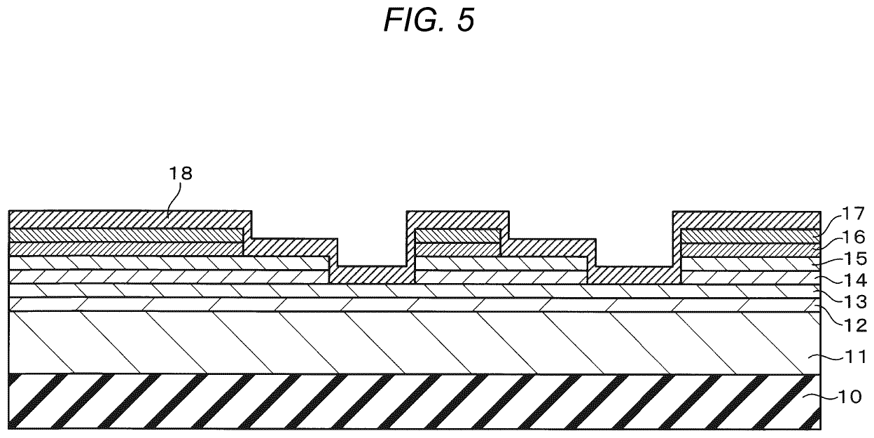

Next, the p-type layer 18 is formed continuously on the electron blocking layer 17, on the non-doped intermediate layer of the second intermediate layer 15 exposed by the first groove 30, and on the non-doped intermediate layer of the first intermediate layer 13 exposed by the second groove 31 (see FIG. 5).

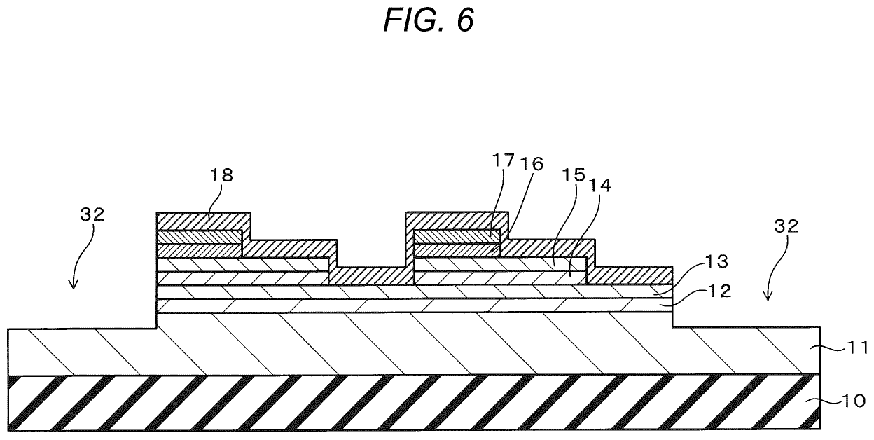

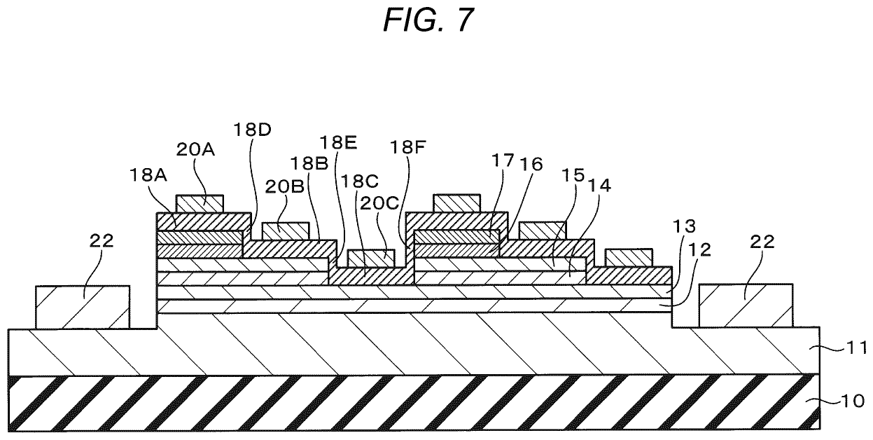

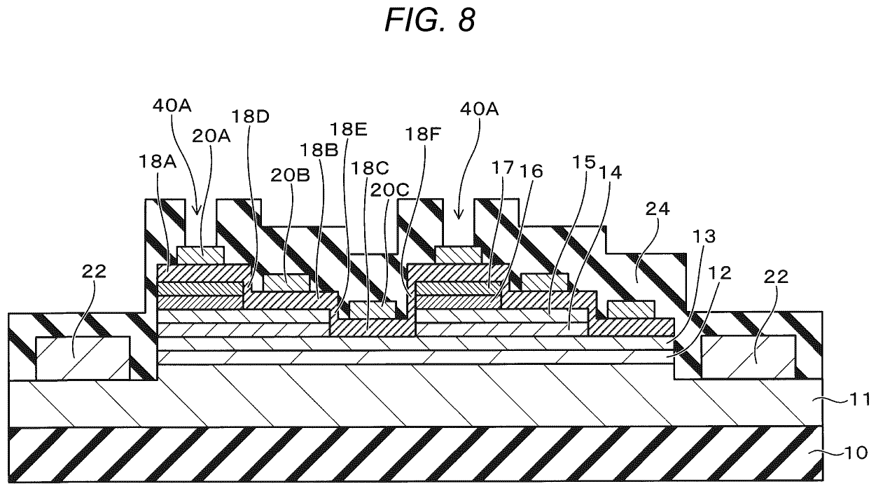

Next, a partial region on the surface of the p-type layer 18 is dry-etched until it reaches the n-type layer 11 to form the third groove 32 (see FIG. 6). The planar pattern of the third groove 32 is a annular pattern along the outer periphery of the element. Then, the n-side contact electrode 22 is formed on the n-type layer 11 exposed on the bottom surface of the third groove 32, and the p-side contact electrodes 20A to 20C are formed at predetermined positions (on the regions 18A to 18C) on the p-type layer 18, respectively (see FIG. 7). The n-side contact electrode 22 may be formed before or after the p-side contact electrodes 20A to 20C. Next, the insulating film 24 is formed to cover the entire upper surface. That is, the insulating film 24 is formed to cover the p-side contact electrodes 20A to 20C, the p-type layer 18, the n-side contact electrode 22, and the side surface and the bottom surface of the third groove 32. Then, the holes 40A to 40D are formed at predetermined positions in the insulating film 24 (see FIG. 8). The holes 40A to 40C have a depth reaching the p-side contact electrodes 20A to 20C, respectively, and the hole 40D has a depth reaching the n-side contact electrode 22.

Next, the p-side electrodes 21A to 21C and the n-side electrode 23 are respectively formed at predetermined positions on the insulating film 24, the p-side contact electrodes 20A to 20C are connected to the p-side electrodes 23A to 23C via the holes 40A to 40C, respectively, and the n-side contact electrode 22 is connected to the n-side electrode 23 via the hole 40D. With the above, the light emitting element according to the first embodiment shown in FIG. 1 and FIGS. 2A and 2B is produced.

### First Modification of First Embodiment

At present, in the light emitting element containing a Group III nitride semiconductor, light emission efficiency of red light is lower than that of green light and blue light. Therefore, an area of the p-side contact electrode 20A may be made larger than areas of the p-side contact electrode 20B and the p-side contact electrode 20C. When the area of red light emission is made larger than the areas of green light emission and blue light emission, adjustment of the color balance can be made easier.

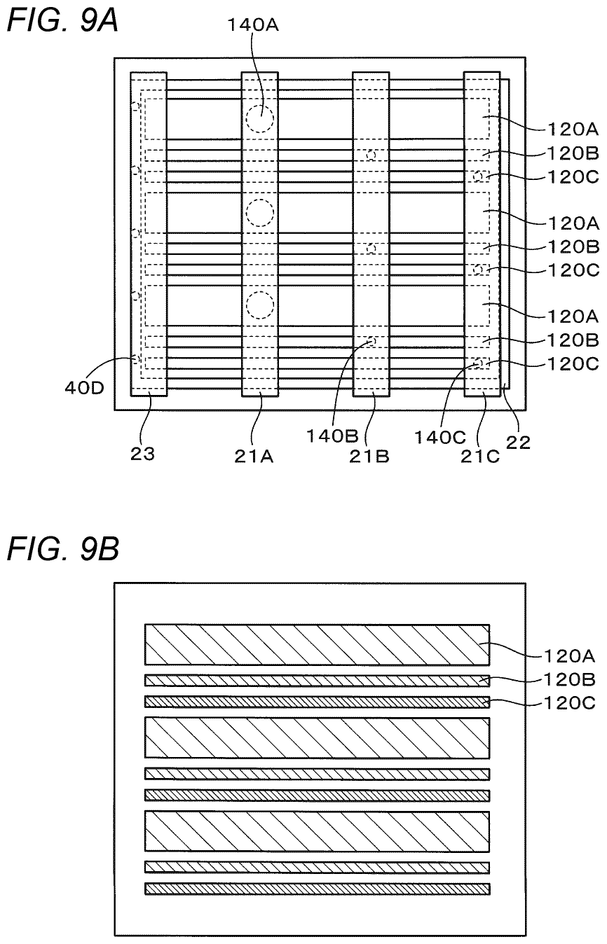

For example, in the first embodiment, the p-side contact electrodes 20A to 20C have the same width, but as shown in FIGS. 9A and 9B, a pattern in which a width of a p-side contact electrode 120A is made greater than that of p-side contact electrodes 120B and 120C may be used. FIG. 9B shows only the p-side contact electrodes 120A to 120C. The width of the p-side contact electrode 120A is preferably 2 to 10 times the width of the p-side contact electrode 120B.

In addition, the light emission efficiency of green light is higher than the light emission efficiency of red light, but lower than the light emission efficiency of blue light. Therefore, the width of the p-side contact electrode 120B may be made smaller than the width of the p-side contact electrode 120A and greater than the width of the p-side contact electrode 120C.

### Second Modification of First Embodiment

In the first embodiment, the p-side contact electrodes 20A to 20C are each arranged in a stripe pattern, but in the present invention, it is sufficient to have a pattern in which a plurality of units are arranged in a predetermined direction, each of the units being a pattern including respective one or more of p-side contact electrodes 20A, p-side contact electrodes 20B, and p-side contact electrodes 20C.

The number of each of the p-side contact electrodes 20A to 20C per unit is preferably 2 or less. This is because when the number of each of the p-side contact electrodes 20A to 20C per unit is too large, there is a concern that the color variation may be increased due to the angle.

In addition, the number of units is sufficiently 2 or more, and is preferably 3 to 20. In addition, the arrangement of the units does not necessarily have to be periodic, and is preferably periodic from the viewpoint of reducing the color variation. The predetermined direction may be any direction passing through the element in a plan view. From the viewpoint of ease of element preparation and a reduction in color variation, the predetermined direction is preferably parallel to a certain side of the element having a rectangular shape.

For example, the first region to the third region may be arranged in a stripe pattern, with the first regions connected to each other, the second regions connected to each other, or the third regions connected to each other at end portions in the stripe direction. In this case, the p-side contact electrodes 20A to 20C have a comb-tooth-like pattern or a zigzag pattern. Comb-tooth-like portions of the comb-tooth-like pattern and portions other than bent portions of the zigzag pattern correspond to the first region to the third region in the present invention.

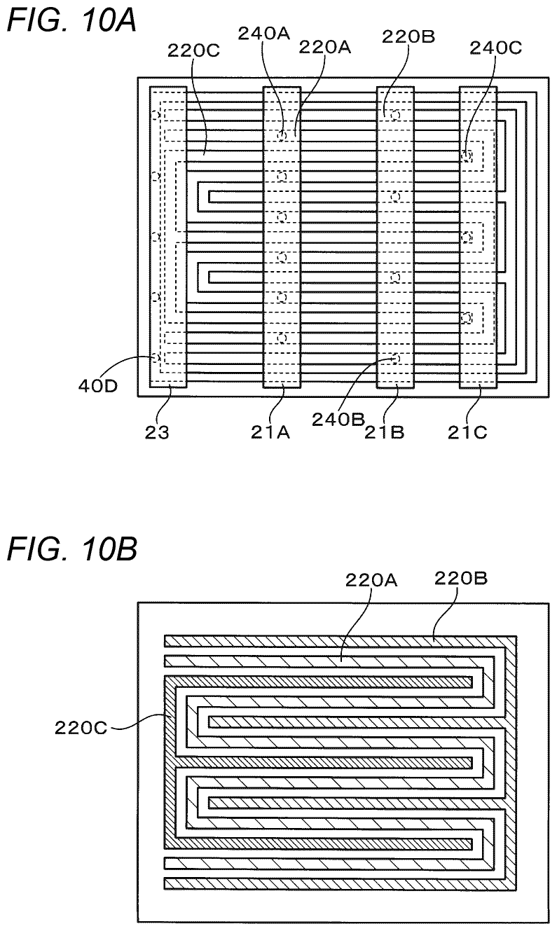

As an example, a planar pattern is as shown in FIGS. 10A and 10B. In FIGS. 10A and 10B, p-side contact electrodes 220B and 220C are formed in a comb-tooth-like pattern, with the comb-tooth interlocking with each other, and a p-side contact electrode 220A is formed in a zigzag pattern between the comb-teeth of the p-side contact electrode 220B and the comb-teeth of the p-side contact electrode 220C. FIG. 10B shows only the pattern of the p-side contact electrodes 220A to 220C. Even with such a pattern, it is possible to reduce a variation in color of the light emitting element due to the viewing angle. In addition, it is easy to make an area of the p-side contact electrode 220A larger than that of the p-side contact electrodes 220B and 220C, and it is easy to balance the light intensity.

### Other Modifications

Although the light emitting element according to the first embodiment has a square shape in the plan view, it may have a rectangular shape. The present invention is particularly effective when the length of the short side of the element in the plan view is 200 μm or more. As the element size increases, the color variation due to the angle increases, but according to the present invention, this can be effectively reduced. Preferably, the length of the short side is 200 μm to 1000 μm, and the length of the long side is 400 μm to 1000 μm.

Although the light emitting element according to the first embodiment emits light of three colors having different emission wavelengths, the present invention can be applied to any light emitting element that emits light of two or more colors having different emission wavelengths. In addition, the structure of the light emitting element is not limited to the structure shown in the first embodiment, but may be any structure having light emitting regions of two or more colors.

Although the light emitting element according to the first embodiment is of the flip chip type, the present invention can also be applied to a face-up type or vertical type element.

The light emitting element according to the first embodiment can be used in display devices and wavelength division multiplexing communications.

### REFERENCE SIGNS LIST

10: substrate
11: n-type layer
12: first active layer
13: first intermediate layer
14: second active layer
15: second intermediate layer
16: third active layer
17: electron blocking layer
18: p-type layer
18A to 18C: region
20A to 20C: p-side contact electrode
21A to 21C: p-side electrode
22: n-side contact electrode
23: n-side electrode
24: insulating film
30: first groove
31: second groove
32: third groove

What is claimed is:

1. A light emitting element, which is a light emitting element containing a Group III nitride semiconductor, having:
a first light emitting region and a second light emitting region having different emission wavelengths, wherein
the first light emitting region has a plurality of first regions,
the second light emitting region has a plurality of second regions,
a planar pattern of the first light emitting region and the second light emitting region is a pattern in which a plurality of units are arranged in a predetermined direction, each of the units being a pattern including one or more of the first regions and one or more of the second regions, and
the plurality of first regions are electrically connected to each other in parallel, and the plurality of second regions are electrically connected to each other in parallel.

2. The light emitting element according to claim 1, wherein a planar pattern of each of: the first regions; and the second regions is a stripe extending in a direction perpendicular to the predetermined direction, and the units are periodically arranged in the predetermined direction.

3. The light emitting element according to claim 1, wherein each of the units includes only one of the first regions and only one of the second regions.

4. The light emitting element according to claim 2, wherein each of the units includes only one of the first regions and only one of the second regions.

5. The light emitting element according to claim 1, wherein
the light emitting element has a rectangular shape in a plan view, and
the predetermined direction is a direction parallel to one of sides of the light emitting element having the rectangular shape.

6. The light emitting element according to claim 2, wherein
the light emitting element has a rectangular shape in a plan view, and
the predetermined direction is a direction parallel to one of sides of the light emitting element having the rectangular shape.

7. The light emitting element according to claim 1, further having:
a third light emitting region having an emission wavelength different from the emission wavelength of the first light emitting region and the emission wavelength of the second light emitting region, wherein
the third light emitting region has a plurality of third regions,
a planar pattern of the first light emitting region, the second light emitting region, and the third light emitting region is a pattern in which a plurality of units are arranged in the predetermined direction, each of the units being a pattern including one or more of the first regions, one or more of the second regions, and one or more of the third regions, and
the plurality of third regions are electrically connected to each other in parallel.

8. The light emitting element according to claim 7, wherein a planar pattern of each of: the first regions; the second regions; and the third regions is a stripe extending in a direction perpendicular to the predetermined direction, and the units are periodically arranged in the predetermined direction.

9. The light emitting element according to claim 7, wherein each of the units includes only one of the first regions, only one of the second regions, and only one of the third regions.

10. The light emitting element according to claim 8, wherein each of the units includes only one of the first regions, only one of the second regions, and only one of the third regions.

11. The light emitting element according to claim 7, wherein
the light emitting element has a rectangular shape in a plan view, and
the predetermined direction is a direction parallel to one of sides of the light emitting element having the rectangular shape.

12. The light emitting element according to claim 8, wherein
the light emitting element has a rectangular shape in a plan view, and the predetermined direction is a direction parallel to one of sides of the light emitting element having the rectangular shape.

13. The light emitting element according to claim 7, wherein the first light emitting region emits red light, the second light emitting region emits green light, and the third light emitting region emits blue light, and an area of the first light emitting region is larger than an area of the second light emitting region and an area of the third light emitting region.

14. The light emitting element according to claim 8, wherein the first light emitting region emits red light, the second light emitting region emits green light, and the third light emitting region emits blue light, and an area of the first light emitting region is larger than an area of the second light emitting region and an area of the third light emitting region.

15. The light emitting element according to claim 8, wherein the first light emitting region emits red light, the second light emitting region emits green light, and the third light emitting region emits blue light, and a stripe width of the first regions is 2 to 10 times a stripe width of the second regions.

16. The light emitting element according to claim 1, comprising:
a substrate;
an n-type layer provided over the substrate and containing an n-type Group III nitride semiconductor;
a first active layer provided over the n-type layer and having a predetermined band gap energy;
a first intermediate layer provided over the first active layer and containing a Group III nitride semiconductor;
a second active layer provided over the first intermediate layer and having a band gap energy different from the band gap energy of the first active layer;
a first groove having a depth reaching the first intermediate layer from a side of the second active layer;
a p-type layer provided over the second active layer and over a bottom surface of the first groove, and containing a p-type Group III nitride semiconductor;
a first p-side contact electrode provided over the p-type layer; and
a second p-side contact electrode provided over the bottom surface of the first groove, wherein
a region in the second active layer under the first p-side contact electrode is the first light emitting region, and
a region in the first active layer under the second p-side contact electrode is the second light emitting region.

17. The light emitting element according to claim 7, comprising:
a substrate;
an n-type layer provided over the substrate and containing an n-type Group III nitride semiconductor;
a first active layer provided over the n-type layer and having a predetermined band gap energy;
a first intermediate layer provided over the first active layer and containing a Group III nitride semiconductor;
a second active layer provided over the first intermediate layer and having a band gap energy different from the band gap energy of the first active layer;
a second intermediate layer provided over the second active layer and containing a Group III nitride semiconductor;
a third active layer provided over the second intermediate layer and having a band gap energy different from the band gap energy of the first active layer and the band gap energy of the second active layer;
a first groove having a depth reaching the second intermediate layer from a side of the third active layer;
a second groove having a depth reaching the first intermediate layer from a side of the third active layer;
a p-type layer provided over the third active layer, over a bottom surface of the first groove, and over a bottom surface of the second groove, and containing a p-type Group III nitride semiconductor;
a first p-side contact electrode provided over the p-type layer;
a second p-side contact electrode provided over the bottom surface of the first groove; and
a third p-side contact electrode provided over the bottom surface of the second groove, wherein
a region in the third active layer under the first p-side contact electrode is the first light emitting region, a
region in the second active layer under the second p-side contact electrode is the second light emitting region, and
a region in the first active layer under the third p-side contact electrode is the third light emitting region.

18. The light emitting element according to claim 17, further comprising:
a third groove having a depth reaching the n-type layer from a side of the third active layer; and
an n-side contact electrode provided over a bottom surface of the third groove, wherein
a planar pattern of each of the third groove and the n-side contact electrode is a rectangular annular pattern along an outer periphery of the element.
